(19) United States
(12) Patent Application Publication
(10) Pub. No.: US 2019/0379307 A1
(43) Pub. Date: Dec. 12, 2019

(54) Magnetic Explosive Engine

(71) Applicant: Cuifei Cheng, Huangshan City (CN)

(72) Inventor: Cuifei Cheng, Huangshan City (CN)

(21) Appl. No.: 16/003,409

(22) Filed: Jun. 8, 2018

(51) Int. Cl. H02N 10/00; H02K 53/00; F03G 7/06; H01L 37/04

(52) U.S. Cl. CPC H02N 10/00; H02K 53/00; H02K 35/02; H01L 37/04; F03G 7/06

(57) ABSTRACT

The present invention provides a magnetic explosion engine comprising: a stator comprising a supporting disk and a plurality of low-temperature Curie point magnets provided on the supporting disk, wherein the supporting disk is of a disk-shaped structure, and the low-temperature Curie point magnets are all evenly distributed along the circumference of the supporting disk and are all centrally symmetrical about the center of a circle of the supporting disk. The low-temperature Curie point magnets are relative to the Curie point temperature of a normal magnet. The magnetic explosion engine provided by the present invention transmits heat and starts a high-temperature and low-temperature automatic switching procedure. With the use of a low-temperature Curie point magnet, the magnetic force disappears and recovers when its temperature changes, expressing a zero-resistance magnetic field motion.

### TECHNICAL FIELD

The present invention relates to the field of energy conversion and utilization, in particular to a magnetic explosion engine.

### BACKGROUND

At present, most of the power sources for vehicles and boats are from a piston-type internal combustion engine. At work, energy efficiency is low. Only 25% of thermal energy is converted into mechanical energy when the fuel burns and expands, while the remaining 75% requires good discharging facilities to be discharged. The fuel that is not completely burnt is discharged while noise is generated. The discharged exhaust gas contains a large amount of harmful gases, resulting in environmental pollution. The piston-type internal combustion engine has a complex manufacturing process, requiring complicated oil circuits, intake and exhaust systems, mixing oil and gas, pressurizing, and cooling devices. The piston-type internal combustion engine is greatly affected by the ambient temperature.

### SUMMARY

In order to solve the above technical problems, there is provided a magnetic explosion engine that generates power with the interaction between a low-temperature Curie point magnet and a neodymium-iron-boron magnet.

A magnetic explosion engine comprises:

a stator comprising a supporting disk and a plurality of low-temperature Curie point magnets provided on the supporting disk, wherein the supporting disk is of a disk-shaped structure, the low-temperature Curie point magnets are all evenly distributed along the circumference of the supporting disk and are all centrally symmetrical about the center of a circle of the supporting disk, and the low-temperature Curie point magnet is relative to the Curie point temperature of a normal magnet;

a rotor comprising a high-temperature disk, a low-temperature disk, and permanent magnets, the number of which is equal to one-half of the number of the low-temperature Curie point magnets, wherein the high-temperature disk and the low-temperature disk are provided on both sides of the stator, respectively, and are fixedly connected by a heat-insulated column, two centrally symmetrical low-temperature Curie point magnets are in contact with and cooperate with the high-temperature disk and the low-temperature disk, respectively, the number of the permanent magnet combinations is one-half of the number of the low-temperature Curie point magnets, the permanent magnets are all provided on the lower side of the low-temperature disk, and the magnetic poles of each of the permanent magnets interact with the two centrally symmetrical low-temperature Curie point magnets so that the high-temperature disk and the low-temperature disk which are conjoined generate a magnetic force effect between two adjacent low-temperature Curie point magnets, the temperatures of both the high-temperature disk and the low-temperature disk are relative to the Curie point temperature of the low-temperature Curie point magnet, the temperature of the high-temperature disk is higher than the Curie point temperature, and the temperature of the low-temperature disk is lower than the Curie point temperature; and

an output mechanism which is connected to the rotor in a transmission manner and converts the motion of the rotor into continuous rotation.

The number of the stators is two, the two stators are symmetrically provided on the upper and lower sides of the permanent magnets about the permanent magnets, and each of the stators is provided with the high-temperature disk and the low-temperature disk.

The permanent magnet comprises a strip magnet, a small magnet, and a concave soft iron, wherein a side wall of the concave soft iron forms a protrusion in a manner facing and far from the concave soft iron, one end of the strip magnet is fixedly provided in the protrusion, and the small magnet is provided on one side inside the concave soft iron and away from the strip magnet.

At least one concave soft iron is connected to each of the strip magnets, and each of the concave soft irons is provided with one of the small magnets.

The magnetic pole at one end of the strip magnet connected to the concave soft iron is the same as the magnetic pole at one end of the small magnet facing the strip magnet.

When the number of the stators is one, the strip magnet forms an included angle with the horizontal plane and passes through the center of the supporting disk; when the number of the stators is two, the strip magnet is placed horizontally.

The high-temperature disk comprises a fixed high-temperature ring and at least three high-temperature fan-shaped blocks provided on the circumference of the fixed high-temperature ring, the adjacent high-temperature fan-shaped blocks and the center of the circle of the fixed high-temperature ring form the same included angle, each of the high-temperature fan-shaped blocks forms a soft iron toward the stator in contact with the low-temperature Curie point magnet, the low-temperature disk comprises a fixed low-temperature ring and low-temperature fan-shaped blocks provided on the circumference of the fixed low-temperature ring, the number of the low-temperature fan-shaped blocks is the same as the number of the high-temperature fan-shaped blocks, one of the low-temperature fan-shaped blocks is provided between two adjacent high-temperature fan-shaped blocks, the fixed high-temperature ring and the fixed low-temperature ring are fixedly provided by the heat-insulated column, one of the low-temperature Curie point magnets is provided between the high-temperature fan-shaped block and the low-temperature fan-shaped block, and the low-temperature Curie point magnet oscillates and is interfaced with the low-temperature Curie point magnet.

The supporting disk is provided with an arc-shaped hole, the heat-insulated column passes through the arc-shaped hole and is fixedly provided together with the high-temperature disk and the low-temperature disk, respectively, and the heat-insulated column is slidable within the arc-shaped hole as the high-temperature ring and the low temperature ring which are conjoined oscillate back and forth; a high-temperature and low-temperature automatic switching procedure starts to work.

The low-temperature Curie point magnet is made of Cu_{0.45}Zn_{0.55}Ti_{0.03}Fe_{1.97}O₄ material.

The temperature of the high-temperature disk is greater than 50° C., and the temperature of the low-temperature disk is 15° C.

Each of the low-temperature Curie point magnets comprises at least four small low-temperature Curie point magnets and a heat-sensitive metal, the heat-sensitive metal forms a grid-like structure, and each of the grids is provided with one of the small low-temperature Curie point magnets.

In the magnetic explosion engine provided by the present invention, with the use of a low-temperature Curie point magnet, the magnetic force disappears and recovers when its temperature changes. The magnetic explosion engine transmits heat and starts a high-temperature and low-temperature automatic switching procedure. The low-temperature Curie point magnets are subjected to continuously demagnetizing, re-magnetizing, demagnetizing, and re-magnetizing; in the intersection with a circle of three neodymium-iron-boron magnetic fields, six low-temperature Curie point magnets circulate in a circle, no resistance enters, and an explosive force is discharged; that is, the directional movement of the rotor is promoted by a continuous magnetic explosive force. The generated power is converted into continuous rotation through an output device to achieve the purpose of outputting power. A high-temperature disk may use energy sources such as electric heating, and does not consume non-renewable energy sources such as gasoline to protect the environment.

### BRIEF DESCRIPTION OF THE DRAWINGS

FIG. 1 is a schematic diagram illustrating a structure of a stator of a magnetic explosion engine according to the present invention;

FIG. 2 is a schematic diagram illustrating a structure of two stators of a magnetic explosion engine according to the present invention;

FIG. 3 is a schematic diagram illustrating a structure of a low-temperature disk of a magnetic explosion engine according to the present invention;

FIG. 4 is a schematic diagram illustrating a structure of a high-temperature disk of a magnetic explosion engine according to the present invention;

FIG. 5 is a top diagram of a combination of a stator and a rotor of a magnetic explosion engine according to the present invention;

FIG. 6 is a schematic diagram illustrating a structure of a stator of a magnetic blast engine according to the present invention;

FIG. 7 is a schematic diagram illustrating a structure of a permanent magnet of a magnetic explosion engine according to the present invention;

FIG. 8 is a schematic diagram illustrating a structure of a low-temperature Curie point magnet of a magnetic explosion engine according to the present invention;

FIG. 9 is a schematic diagram illustrating another structure of a low-temperature Curie point magnet of a magnetic explosion engine according to the present invention;

FIG. 10 is a schematic diagram of distribution of a plurality of stators of a magnetic explosion engine according to the present invention; and

FIG. 11 is a schematic diagram illustrating a structure of a combination of a plurality of stators and a plurality of rotors of a magnetic explosion engine according to the present invention.

In the drawing:

1, a stator; 2, a rotor; 11, a supporting disk; 12, a low-temperature Curie point magnet; 21, a high-temperature disk; 22, a low-temperature disk; 23, a permanent magnet; 111, an arc-shaped hole; 121, a small low-temperature Curie point magnet; 122, a heat-sensitive metal; 211, a fixed high-temperature ring; 212, a high-temperature fan-shaped block; 221, a fixed low-temperature ring; 222, a low-temperature fan-shaped block; 231, a strip magnet; 232, a small magnet; 233, a concave soft iron; 234, a protrusion.

### DESCRIPTION OF THE EMBODIMENTS

The present invention will be further described below in detail with reference to the accompanying drawings and the specific embodiments.

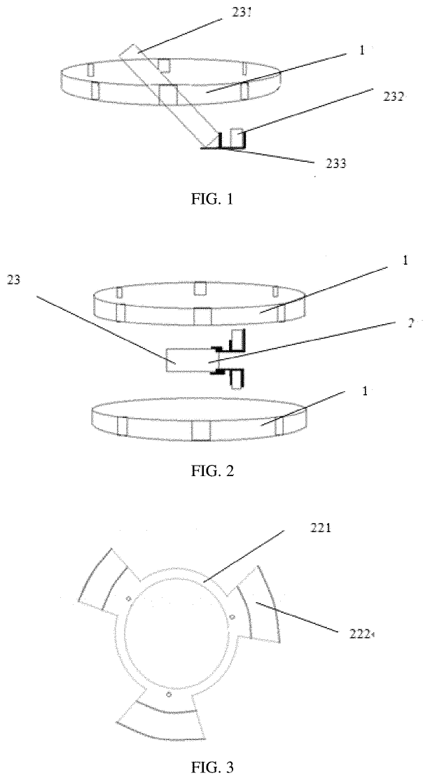

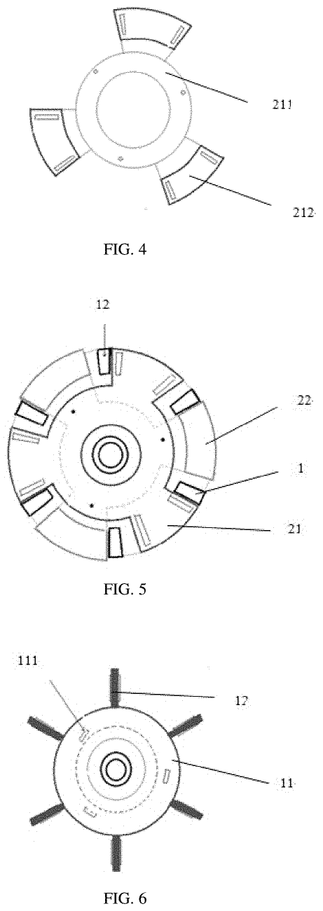

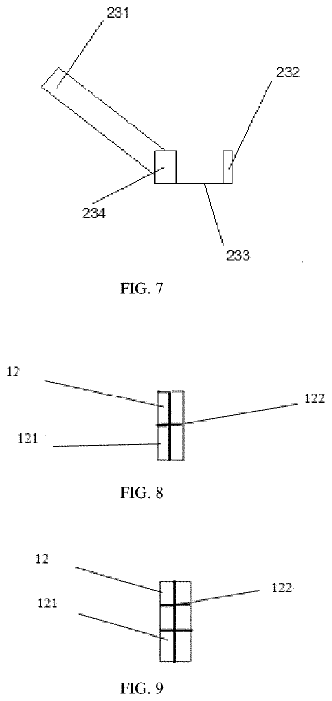

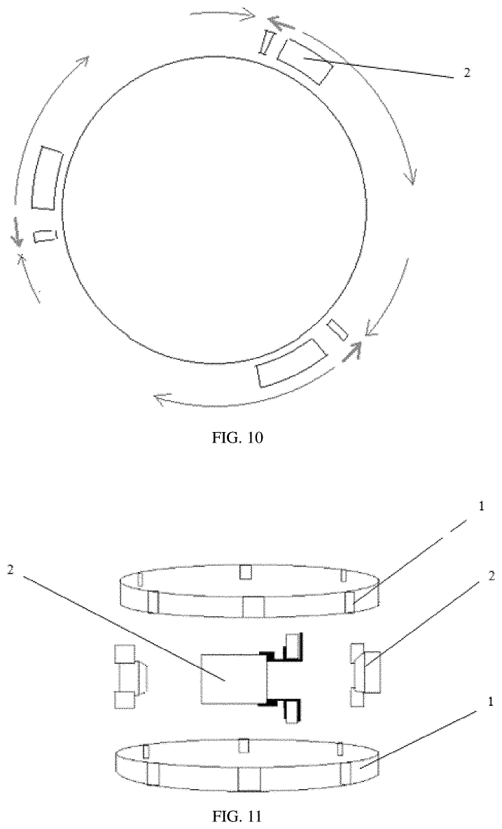

The magnetic explosion engine shown in FIG. 1 to FIG. 11 comprises: a stator 1 comprising a supporting disk 11 and a plurality of low-temperature Curie point magnets 12 provided on the supporting disk 11, wherein the supporting disk 11 is of a disk-shaped structure, the low-temperature Curie point magnets 12 are all evenly distributed along the circumference of the supporting disk 11 and are all centrally symmetrical about the center of a circle of the supporting disk 11, and the low-temperature Curie point magnet 12 is relative to the Curie point temperature of a normal magnet; a rotor 2 comprising a high-temperature disk 21, a low-temperature disk 22, and permanent magnets 23, the number of which is equal to one-half of the number of the low-temperature Curie point magnets 12, wherein the high-temperature disk 21 and the low-temperature disk 22 are provided on both sides of the stator 1, respectively, and are fixedly connected by a heat-insulated column, two centrally symmetrical low-temperature Curie point magnets 12 are in contact with and cooperate with the high-temperature disk 21 and the low-temperature disk 22, respectively, the number of the permanent magnet 23 is one-half of the number of the low-temperature Curie point magnets 12, the permanent magnets 23 are all provided on the lower side of the low-temperature disk 22, and the magnetic poles of each of the permanent magnets 23 interact with the two centrally symmetrical low-temperature Curie point magnets 12 so that a relative motion is generated between the rotor 2 and two adjacent low-temperature Curie point magnets 12, the temperatures of both the high-temperature disk 21 and the low-temperature disk 22 are relative to the Curie point temperature of the low-temperature Curie point magnet 12, the temperature of the high-temperature disk 21 is higher than the Curie point temperature, and the temperature of the low-temperature disk 22 is lower than the Curie point temperature; and an output mechanism (not shown in the figure) which is connected to the rotor 2 in a transmission manner and converts the oscillation of the rotor 2 into continuous rotation.

The Curie temperature means that as the temperature rises, since the thermal oscillation of the elementary particles inside the material is intensified, the arrangement of microscopic magnetic dipole moments inside the magnetic material is gradually disordered, and the magnetic polarization intensity J expressed as a material at the macro level is reduced as the temperature rises. When the temperature rises to a certain value, the magnetic polarization intensity J of the material drops to 0. At this time, the magnetic property of the magnetic material becomes the same as that of non-magnetic materials such as air, and the temperature is referred to as the Curie temperature (denoted as Tc) of the material. The Curie temperature Tc is only related to the composition of the alloy, and has nothing to do with the microstructure of the material and its distribution.

In the present invention, the high-temperature disk 21 and the low-temperature disk 22 are in contact with the low-temperature Curie point magnet 12 in sequence. When the high-temperature disk 21 is in contact with the first low-temperature Curie point magnet 12, the temperature of the first low-temperature Curie point magnet 12 rises. When the temperature of the first low-temperature Curie point magnet 12 reaches or even exceeds its Curie temperature, the magnetic force disappears, and the force of interaction with the permanent magnet 23 disappears. At the same time, another second low-temperature Curie point magnet 12 relative to the first low-temperature Curie point magnet 12 is in contact with the low-temperature disk 22 and the temperature is lowered. The second low-temperature Curie point magnet 12 recovers the magnetic property and recovers the applied force of the permanent magnet 23 because the first low-temperature Curie point magnet 12 and the second low-temperature Curie point magnet 12 are the stator 1, that is, no relative motion occurs with the ground. Under the action of the applied force, the permanent magnet 23, the high-temperature disk 21 and the low-temperature disk 22 (i.e., the rotor 2) are moved so that the low-temperature disk 22 is disengaged from the second low-temperature Curie point magnet 12 to move in the direction of the high-temperature disk 21. The high-temperature disk 21 is disengaged from the low-temperature Curie point magnet 12. The temperature of the first low-temperature Curie point magnet 12 starts to decrease until the first low-temperature Curie point magnet is adhered to the low-temperature disk 22. The first low-temperature Curie point magnet 12 recovers the magnetic force, and starts to generate a magnetic force effect with the permanent magnet 23. At the same time, the second low-temperature Curie point magnet 12 is in contact with the high-temperature disk 21, the temperature rises, the magnetic force disappears, the applied force of the permanent magnet 23 disappears, and the rotor 2 moves at a second time. The above steps are repeated. The magnetic explosion engine transmits heat and starts a high-temperature and low-temperature automatic switching procedure. The low-temperature Curie point magnets 12 are subjected to continuously demagnetizing, re-magnetizing, demagnetizing, and re-magnetizing; in the intersection with a circle of three neodymium-iron-boron magnetic fields, six low-temperature Curie point magnets 12 circulate in a circle, no resistance enters, and an explosive force is discharged; that is, the directional movement of the rotor 2 is promoted by a continuous magnetic explosive force. The output mechanism receives the motion of the rotor 2 and converts the motion into continuous rotation to achieve the purpose of outputting power.

The output mechanism may adopt a transmission linkage structure.

There are several low-temperature Curie point magnets 12, all of which are centrally symmetrical about the center of a circle of the supporting disk 11. The ratio of the number of the permanent magnets 23 to the number of the low-temperature Curie point magnets 12 is 1: 2. The permanent magnet 23 can be fully utilized to further reduce the overall volume of the magnetic explosion engine.

The number of the stators 1 is two, the two stators are symmetrically provided on the upper and lower sides of the permanent magnets 23 about the permanent magnets 23, and each of the stators 1 is provided with the high-temperature disk 21 and the low-temperature disk 22, so that the same permanent magnet 23 can simultaneously act on two pairs of the low-temperature Curie point magnets 12 on the two stators 1 to reduce the overall volume of the magnetic explosion engine.

The permanent magnet 23 comprises a strip magnet 231, a small magnet 232, and a concave soft iron 233, wherein a side wall of the concave soft iron 233 forms a protrusion 234 in a manner facing and far from the concave soft iron 233, one end of the strip magnet 231 is fixedly provided in the protrusion 234, and the small magnet 232 is provided on one side inside the concave soft iron 233 and away from the strip magnet 231. The small magnet 232 and the strip magnet 231 are integrated into a whole by the concave soft iron 233, which can enhance the magnetic force effect of the small magnet 232 on the low-temperature Curie point magnet 12 and increase the motion effect of the rotor 2.

At least one concave soft iron 233 is connected to each of the strip magnets 231, and each of the concave soft irons 233 is provided with one of the small magnets 232.

The magnetic pole at one end of the strip magnet 231 connected to the concave soft iron 233 is the same as the magnetic pole at one end of the small magnet 232 facing the strip magnet 231.

When the number of the stators 1 is one, the strip magnet 231 forms an included angle with the horizontal plane and passes through the center of the supporting disk 11; when the number of the stators 1 is two, the strip magnet 231 is placed horizontally so as to satisfy the maximum force applied to the low-temperature Curie point magnet 12 when the number of the stators 1 is one or two.

The high-temperature disk 21 comprises a fixed high-temperature ring 211 and at least three high-temperature fan-shaped blocks 212 provided on the circumference of the fixed high-temperature ring 211, and the adjacent high-temperature fan-shaped blocks 212 and the center of the circle of the fixed high-temperature ring 211 form the same included angle, the low-temperature disk 22 comprises a fixed low-temperature ring 221 and low-temperature fan-shaped blocks 222 provided on the circumference of the fixed low-temperature ring 221, the number of the low-temperature fan-shaped blocks 222 is the same as the number of the high-temperature fan-shaped blocks 212, one of the low-temperature fan-shaped blocks 222 is provided between two adjacent high-temperature fan-shaped blocks 212, the fixed high-temperature ring 211 and the fixed low-temperature ring 221 are fixedly provided by the heat-insulated column, one of the low-temperature Curie point magnets 12 is provided between the high-temperature fan-shaped block 212 and the low-temperature fan-shaped block 222 by the adjacent soft irons 213, and the soft irons 213 may oscillate relative to the low-temperature Curie point magnet 12 and is interfaced with the low-temperature Curie point magnet 12.

The supporting disk 11 is provided with an arc-shaped hole 111, the heat-insulated column passes through the arc-shaped hole 111 and is fixedly provided together with the high-temperature disk 21 and the low-temperature disk 22, respectively, and the heat-insulated column is slidable within the arc-shaped hole 111 as the rotor 2 oscillates back and forth.

Each of the low-temperature Curie point magnets 12 comprises at least four small low-temperature Curie point magnets 121 and a heat-sensitive metal 122, the heat-sensitive metal 122 forms a grid-like structure, and each of the heat-sensitive metal warp and weft members shuttles between the low-temperature Curie points 121 horizontally and vertically.

The low-temperature Curie point magnet 12 is made of Cu_{0.45}Zn_{0.55}Ti_{0.03}Fe_{1.97}O₄ material at the Curie temperature of 44.9° C.

The temperature of the high-temperature disk 21 is greater than 50° C., and the temperature of the low-temperature disk 22 is 15° C.

The foregoing descriptions are merely preferred embodiments of the present invention and are not intended to limit the present invention. Any minor modifications, equivalent replacements and improvements made to the above embodiments based on the technical essence of the present invention shall be included in the protection scope of the technical solution of the present invention.

What is claimed is:

1. A magnetic explosion engine, comprising:
a stator comprising a supporting disk and a plurality of low-temperature Curie point magnets provided on the supporting disk, wherein the supporting disk is of a disk-shaped structure, and the low-temperature Curie point magnets are all evenly distributed along the circumference of the supporting disk and are all centrally symmetrical about the center of a circle of the supporting disk;
a rotor comprising a high-temperature disk, a low-temperature disk, and permanent magnet combinations, the number of which is equal to one-half of the number of the low-temperature Curie point magnets, wherein the high-temperature disk and the low-temperature disk are provided on both sides of the stator, respectively, and are fixedly connected by a heat-insulated column, two centrally symmetrical low-temperature Curie point magnets are in contact with and cooperate with the high-temperature disk and the low-temperature disk, respectively, the number of the permanent magnets is one-half of the number of the low-temperature Curie point magnets, the permanent magnets are all provided on the lower side of the low-temperature disk, and the magnetic poles of each of the permanent magnets interact with the two centrally symmetrical low-temperature Curie point magnets so that when the rotor meets with the two adjacent low-temperature Curie point magnets, a zero resistance enters the magnetic field, and a repulsive force goes out of the magnetic field, resulting in a relative magnetic force effect; and
an output mechanism which is connected to the rotor in a transmission manner and converts the motion of the rotor into continuous rotation.

2. The magnetic explosion engine according to claim 1, wherein the number of the stators is two, the two stators are symmetrically provided on the upper and lower sides of the permanent magnets about the permanent magnets, and each of the stators is provided with the high-temperature disk and the low-temperature disk.

3. The magnetic explosion engine according to claim 1, wherein the permanent magnet comprises a strip magnet, a small magnet, and a concave soft iron, wherein a side wall of the concave soft iron forms a protrusion in a manner facing and far from the concave soft iron, one end of the strip magnet is fixedly provided in the protrusion, and the small magnet is provided on one side inside the concave soft iron and away from the strip magnet.

4. The magnetic explosion engine according to claim 3, wherein at least one concave soft iron is connected to each of the strip magnets, and each of the concave soft irons is provided with one of the small magnets.

5. The magnetic explosion engine according to claim 3, wherein the magnetic pole at one end of the strip magnet connected to the concave soft iron is the same as the magnetic pole at one end of the small magnet facing the strip magnet.

6. The magnetic explosion engine according to claim 3, wherein when the number of the stators is one, the strip magnet forms an included angle with the horizontal plane and passes through the center of the supporting disk; when the number of the stators is two, the strip magnet is placed horizontally.

7. The magnetic explosion engine according to claim 1, wherein the high-temperature disk comprises a fixed high-temperature ring and at least three high-temperature fan-shaped blocks provided on the circumference of the fixed high-temperature ring, the adjacent high-temperature fan-shaped blocks and the center of the circle of the fixed high-temperature ring form the same included angle, each of the high-temperature fan-shaped blocks forms a soft iron toward the stator in contact with the low-temperature Curie point magnet, the low-temperature disk comprises a fixed low-temperature ring and low-temperature fan-shaped blocks provided on the circumference of the fixed low-temperature ring, the number of the low-temperature fan-shaped blocks is the same as the number of the high-temperature fan-shaped blocks, one of the low-temperature fan-shaped blocks is provided between two adjacent high-temperature fan-shaped blocks, the fixed high-temperature ring and the fixed low-temperature ring are fixedly provided by the heat-insulated column, one of the low-temperature Curie point magnets is provided between the high-temperature fan-shaped block and the low-temperature fan-shaped block, and the low-temperature Curie point magnet oscillates and is interfaced with the low-temperature Curie point magnet.

8. The magnetic explosion engine according to claim 1, wherein the supporting disk is provided with an arc-shaped hole, the heat-insulated column passes through the arc-shaped hole and is fixedly provided together with the high-temperature disk and the low-temperature disk, respectively, and the heat-insulated column is slidable within the arc-shaped hole as the rotor oscillates.

9. The magnetic explosion engine according to claim 1, wherein the low-temperature Curie point magnet is made of Cu_{0.45}Zn_{0.55}Ti_{0.03}Fe_{1.97}O₄ material; the temperature of the high-temperature disk is greater than 50° C., and the temperature of the low-temperature disk is 15° C.

10. The magnetic explosion engine according to claim 1, wherein each of the low-temperature Curie point magnets comprises a heat-sensitive metal warp and weft member and a plurality of small low-temperature Curie point magnets, and the heat-sensitive metal shuttles between the low-temperature Curie points horizontally and vertically.
